(19) United States
(12) Patent Application Publication
(10) Pub. No.: US 2023/0040100 A1
(43) Pub. Date: Feb. 9, 2023

(54) DISPLAY SUBSTRATE, PREPARATION METHOD THEREFOR, AND DISPLAY APPARATUS

(71) Applicant: BOE Technology Group Co., Ltd., Beijing (CN)

(72) Inventors: Chengjie QIN, Beijing (CN); Shantao CHEN, Beijing (CN); Fangxu CAO, Beijing (CN); Tao SUN, Beijing (CN); Song ZHANG, Beijing (CN); Rui HONG, Beijing (CN); Ziyu ZHANG, Beijing (CN)

(21) Appl. No.: 17/787,953

(22) PCT Filed: Aug. 9, 2021
(86) PCT No.: PCT/CN2021/111580

§ 371 Date: Jun. 22, 2022

(30) Foreign Application Priority Data
Sep. 16, 2020 (CN) 202010973170.3

(51) Int. Cl. H01L 51/52; H01L 51/00; H01L 51/56; H01L 27/32

(52) U.S. Cl. CPC H01L 51/5253; H01L 51/0097; H01L 51/56; H01L 27/3276; H01L 2227/323

(57) ABSTRACT

A display substrate, a preparation method therefor, and a display apparatus. The display substrate comprises: a plurality of pixel island areas that are separated from one another, a plurality of hole areas, and a connection bridge area that connects the plurality of pixel island areas. The hole areas each comprise a base substrate and an encapsulation layer, the base substrate is provided with an aperture, a barrier structure is provided on the side of the base substrate close to the aperture, and the encapsulation layer covers the side of the base substrate close to the aperture.

### CROSS-REFERENCE TO RELATED APPLICATIONS

The present application is a U.S. National Phase Entry of International PCT Application No. PCT/CN2021/111580, having an international filing date of Aug. 9, 2021, which claims priority to Chinese patent application No. 202010973170.3, entitled “display substrate, preparation method therefor, and display apparatus”, filed to the CNIPA on Sep. 16, 2020, and the contents disclosed in the above-mentioned applications are hereby incorporated as a part of this application.

### TECHNICAL FIELD

Embodiments of the present disclosure relate to, but are not limited to, the field of display technology, in particular to a display substrate, a method for preparing the display substrate, and a display apparatus.

### BACKGROUND

An Organic Light Emitting Diode (OLED), as an active light emitting display device, has advantages such as self-luminance, wide viewing angle, high contrast, relatively low power consumption, and very quick response. With continuous development of the display technology, the OLED technology is increasingly applied to flexible display apparatuses, and flexible display apparatuses are gradually developing from a two-dimensional directional variable mode to a three-dimensional directional variable mode.

An island-bridge structure is usually used in a flexible OLED display substrate with the three-dimensional directional variable mode. The island-bridge structure is formed by providing light emitting units in pixel island areas and providing connection lines between the pixel island areas in connection bridge areas. When an external tensile force is applied, deformation mainly occurs in the connection bridge areas, and the light emitting units of the pixel island areas substantially keep their original shape, and may be prevented from being damaged. In order to increase deformability of the flexible display apparatus, the periphery of the pixel island area is further provided with a hole area having multiple microporous structures, wherein the microporous structures penetrate through a flexible base substrate.

### SUMMARY

The following is a summary of subject matters described herein in detail. The summary is not intended to limit the scope of protection of claims.

An embodiment of the present disclosure provides a display substrate, including a plurality of pixel island areas separated from one another, a plurality of hole areas and a connection bridge area connecting the plurality of pixel island areas, wherein a hole area including a base substrate and an encapsulation layer, the base substrate is provided with an aperture and provided with a barrier structure on a side of the base substrate close to the aperture, and the encapsulation layer covers the side of the base substrate close to the aperture.

In an exemplary embodiment, the barrier structure is provided as a barrier groove, a notch of the barrier groove faces the aperture, and a thickness of the encapsulation layer inside the barrier groove is smaller than a thickness of the encapsulation layer outside the barrier groove, or the encapsulation layer inside the barrier groove is discontinuous.

In an exemplary embodiment, the hole area further includes a composite insulation layer provided on the base substrate, the encapsulation layer covers the composite insulation layer, the composite insulation layer includes a first end face facing the aperture, the base substrate includes a first barrier layer, a buffer layer and a second barrier layer which are stacked, and the first barrier layer includes a second end face facing the aperture, the buffer layer includes a third end face facing the aperture, and the second barrier layer includes a fourth end face facing the aperture.

In a direction parallel to the base substrate, a distance between the second end face and the first end face is smaller than a distance between the third end face and the first end face, a distance between the fourth end face and the first end face is smaller than the distance between the third end face and the first end face, the third end face is provided as a groove bottom of the barrier groove, and opposite surfaces of the first barrier layer and the second barrier layer are provided as sidewalls of the barrier groove.

In an exemplary embodiment, the base substrate includes a first flexible base substrate layer and a second flexible base substrate layer, the first flexible base substrate layer is provided on a side of the first barrier layer away from the buffer layer, the second flexible base substrate layer is provided on a side of the second barrier layer away from the buffer layer, the first flexible base substrate layer includes a fifth end face facing the aperture, and the second flexible base substrate layer includes a sixth end face facing the aperture.

In the direction parallel to the base substrate, a distance between the fifth end face and the first end face is larger than the distance between the second end face and the first end face, larger than the distance between the fourth end face and the first end face, and smaller than the distance between the third end face and the first end face, a distance between the sixth end face and the first end face is larger than the distance between the second end face and the first end face, larger than the distance between the fourth end face and the first end face, and smaller than the distance between the third end face and the first end face.

In an exemplary embodiment, the fifth end face is flush with the sixth end face, and the second end face is flush with the third end face.

In an exemplary embodiment, the barrier groove has a depth ranging from 0.2 microns to 2 microns and a width ranging from 0.2 microns to 2 microns.

In an exemplary embodiment, in a direction perpendicular to the base substrate, a width of the barrier groove is smaller than or equal to the thickness of the encapsulation layer outside the barrier groove.

In an exemplary embodiment, the barrier structure is provided as a barrier eave, the barrier eave extends into the aperture, the barrier eave is configured to form a groove structure with the rigid substrate, a thickness of the encapsulation layer within the groove structure is smaller than a thickness of the encapsulation layer outside the groove structure, or the encapsulation layer within the groove structure is discontinuous.

In an exemplary embodiment, the base substrate includes a buffer layer and a first barrier layer provided on the buffer layer, the first barrier layer extends into the aperture and protrudes beyond the buffer layer to form an eave structure, and the barrier eave includes a portion of the first barrier layer protruding beyond the buffer layer.

In an exemplary embodiment, a length of the first barrier layer protruding beyond the buffer layer ranges from 0.2 microns to 2 microns, and a thickness of the buffer layer ranges from 0.2 microns to 2 microns.

In an exemplary embodiment, further including an organic light emitting layer and a cathode, the organic light emitting layer and the cathode of the hole area are partially provided on the barrier eave.

An embodiment of the present disclosure further provides a method for preparing a display substrate, including:

forming multiple pixel island areas separated from each other, multiple hole areas and a connection bridge area connecting the multiple pixel island areas on a base substrate, the base substrate of a hole area is provided with an aperture, and a side of the base substrate close to the aperture is provided with a barrier structure; and

forming an encapsulation layer, wherein the encapsulation layer covers a sidewall of the base substrate close to the aperture, and the barrier structure is configured to form a fracture zone on the encapsulation layer that can break when the base substrate is lifted off from the rigid substrate.

In an exemplary embodiment, forming the multiple pixel island areas separated from each other, the multiple hole areas and the connection bridge area connecting the multiple pixel island areas on the base substrate includes:

forming a first flexible base substrate layer;

sequentially depositing a first barrier thin film, a buffer thin film and a second barrier thin film on the first flexible base substrate layer, and patterning the second barrier thin film by a patterning process to form a first barrier layer, a buffer layer, a second barrier layer and a first opening which are stacked, wherein the first opening is provided in the hole area and expose the first flexible base substrate layer;

etching the buffer layer, a surface of the buffer layer facing the first opening is recessed in a direction away from the first opening with respect to surfaces of the first barrier layer and the second barrier layer facing the first opening to form a barrier groove with a notch facing the first opening, barrier groove has a depth ranging from 0.2 microns to 2 microns, and a width ranging from 0.2 microns to 2 microns.

In an exemplary embodiment, forming the multiple pixel island areas separated from each other, the multiple hole areas and the connection bridge area connecting the multiple pixel island areas on the base substrate includes:

forming a buffer layer on a rigid substrate;

depositing a first barrier thin film on the buffer layer, patterning the first barrier thin film by a patterning process to form a first barrier layer and a first aperture, wherein the first aperture is located in the hole area, the buffer layer and the first barrier layer within the first aperture are etched away to expose the rigid substrate, the first aperture includes a first hole diameter area formed in the first barrier layer and a second hole diameter area formed in the buffer layer, a hole diameter of the first hole diameter area is smaller than a hole diameter of the second hole diameter area, a barrier eave is formed at a corresponding position of the first barrier layer and the second hole diameter area, and the barrier eave forms a barrier structure.

In an exemplary embodiment, forming the multiple pixel island areas separated from each other, the multiple hole areas and the connection bridge area connecting the multiple pixel island areas on the base substrate includes:

forming a buffer layer on a rigid substrate;

depositing a first barrier thin film on the buffer layer, and patterning the first barrier thin film by a patterning process to form a first barrier layer and a via hole, wherein the via hole is located in the hole area, the via hole is an annular hole, the first barrier layer within the via hole is etched away to expose the buffer layer, and the hole diameter of the via hole ranges between 0.2 microns and 2 microns;

etching the buffer layer to form an inner enlarging hole, wherein the inner enlarging hole is formed in the hole area and corresponds to the position of the via hole, the buffer layer within the inner enlarging hole is etched away to expose the rigid substrate, the hole diameter of the inner enlarging hole is larger than that of the via hole, a barrier eave is formed at the position of the first barrier layer on two sides of the via hole corresponding to the inner enlarging hole, and the barrier eave forms a barrier structure.

An embodiment of the present disclosure further provides a display apparatus including the above display substrate of the above embodiments.

Other aspects may be understood upon reading and understanding of the accompanying drawings and detailed descriptions.

### BRIEF DESCRIPTION OF DRAWINGS

Accompanying drawings are used to provide further understanding of technical solutions of the present disclosure, constitute a part of the specification, and are used to explain the technical solutions of the present disclosure together with embodiments of the present disclosure, thus do not constitute a limitation on the technical solutions of the present disclosure.

FIG. 1 is a schematic plan view of a display substrate according to an exemplary embodiment of the present disclosure.

FIG. 2 is a cross sectional view at position a-a in FIG. 1.

FIG. 3 is a schematic diagram of a structure after a first opening is formed according to an exemplary embodiment of the present disclosure.

FIG. 4 is a schematic diagram of a structure after a second flexible base substrate layer is formed according to an exemplary embodiment of the present disclosure.

FIG. 5 is a schematic diagram of a structure after a pixel definition layer and an isolation dam is formed according to an exemplary embodiment of the present disclosure.

FIG. 6 is a schematic diagram of a structure after a second opening is formed according to an exemplary embodiment of the present disclosure.

FIG. 7 is a schematic diagram of a structure forming a third opening is formed according to an exemplary embodiment of the present disclosure.

FIG. 8 is a schematic diagram of a structure after a barrier groove is formed according to an exemplary embodiment of the present disclosure.

FIG. 9 is a schematic diagram of a structure after an organic light emitting layer and a cathode are formed according to an exemplary embodiment of the present disclosure.

FIG. 10 is a schematic diagram of a structure after an encapsulation layer is formed according to an exemplary embodiment of the present disclosure.

FIG. 11 is a schematic diagram of a structure of another display substrate according to an exemplary embodiment of the present disclosure.

FIG. 12 is a schematic diagram of a structure after a barrier eave is formed according to another exemplary embodiment of the present disclosure.

FIG. 13 is a schematic diagram of a structure after a first barrier layer is formed according to another exemplary embodiment of the present disclosure.

FIG. 14 is a schematic diagram of a structure after a second barrier layer is formed according to another exemplary embodiment of the present disclosure.

FIG. 15 is a schematic diagram of a structure after a second barrier layer is formed according to another exemplary embodiment of the present disclosure.

FIG. 16 is a schematic diagram of a structure after a pixel definition layer and an isolation dam are formed according to another exemplary embodiment of the present disclosure.

FIG. 17 is a schematic diagram of a structure after a third aperture is formed according to another exemplary embodiment of the present disclosure.

FIG. 18 is a schematic diagram of a structure after an aperture is formed according to another exemplary embodiment of the present disclosure.

FIG. 19 is a schematic diagram of a structure after an organic light emitting layer and a cathode are formed according to another exemplary embodiment of the present disclosure.

FIG. 20 is a schematic diagram of a structure after an encapsulation layer is formed according to another exemplary embodiment of the present disclosure.

FIG. 21 is a schematic diagram of a structure after a fourth insulation layer is formed according to an exemplary embodiment of the present disclosure.

FIG. 22 is a schematic diagram of a structure after a first window is formed according to another exemplary embodiment of the present disclosure.

FIG. 23 is a schematic diagram of a structure after a second window is formed according to another exemplary embodiment of the present disclosure.

FIG. 24 is a schematic diagram of a structure after a third window is formed according to another exemplary embodiment of the present disclosure.

FIG. 25 is a schematic diagram of a structure after a fourth window is formed according to another exemplary embodiment of the present disclosure.

FIG. 26 is a schematic diagram of a structure after a via hole is formed according to another exemplary embodiment of the present disclosure.

FIG. 27 is a schematic diagram of a structure after an inner enlarging hole is formed according to another exemplary embodiment of the present disclosure.

FIG. 28 is a schematic diagram of a structure after an organic light emitting layer and a cathode are formed according to another exemplary embodiment of the present disclosure.

FIG. 29 is a schematic diagram of a structure after an encapsulation layer according to another exemplary embodiment of the present disclosure.

### DETAILED DESCRIPTION

The embodiments of the present disclosure will be described in detail below with reference to the drawings. It is to be noted that implementation modes may be implemented in multiple different forms. Those of ordinary skills in the art may easily understand such a fact that embodiments and contents may be transformed into various forms without departing from the purpose and scope of the present disclosure. Therefore, the present disclosure should not be explained as being limited to contents described in following implementation modes only. The embodiments in the present disclosure and features in the embodiments may be combined randomly with each other if there is no conflict.

In the drawings, a size of each constituent element, and a thickness of a layer or a region are exaggerated sometimes for clarity. Therefore, one embodiment of the present disclosure is not necessarily limited to the size, and shapes and sizes of various components in the drawings do not reflect actual scales. In addition, the drawings schematically illustrate ideal examples, and one embodiment of the present disclosure is not limited to the shapes, numerical values, or the like shown in the drawings.

Ordinal numerals such as “first”, “second”, and “third” in the specification are set to avoid confusion between constituent elements, but not to set a limit in quantity.

In the specification, for convenience, wordings indicating directional or positional relationships, such as “center”, “upper”, “lower”, “front”, “back”, “vertical”, “horizontal”, “top”, “bottom”, “inside”, and “outside”, are used for illustrating positional relationships between constituent elements with reference to the drawings, and are merely for facilitating the description of the specification and simplifying the description, rather than indicating or implying that a referred apparatus or element must have a particular orientation and be constructed and operated in the particular orientation. Therefore, they cannot be understood as limitations on the present disclosure. The positional relationships between the constituent elements may be changed as appropriate according to directions according to which the constituent elements are described. Therefore, appropriate replacements may be made according to situations without being limited to the wordings described in the specification.

In the specification, unless otherwise specified and defined explicitly, terms “mount”, “mutually connect”, and “connect” should be understood in a broad sense. For example, a connection may be a fixed connection, or a detachable connection, or an integrated connection. It may be a mechanical connection or an electrical connection. It may be a direct mutual connection, or an indirect connection through middleware, or internal communication between two components. Those of ordinary skills in the art may understand meanings of the above-mentioned terms in the present disclosure according to situations.

In the specification, “parallel” refers to a state in which an angle formed by two straight lines is above −20° and below 20°, and thus also includes a state in which the angle is above −5° and below 5°. In addition, “perpendicular” refers to a state in which an angle formed by two straight lines is above 80° and below 100°, and thus also includes a state in which the angle is above 85° and below 95°.

In the specification, a “film” and a “layer” are interchangeable. For example, a “conductive layer” may be replaced with a “conductive film” sometimes. Similarly, an “insulation film” may be replaced with an “insulation layer” sometimes.

In a flexible OLED display substrate, a flexible layer is usually formed on a rigid substrate, and then the flexible layer is lifted off from the rigid substrate by laser lift off (LLO) process. As for a flexible OLED display substrate with a microporous structure, when the flexible OLED display substrate is lifted off from the rigid substrate, an encapsulation layer on a sidewall of the microporous structure will break, which will then reduce the reliability of encapsulation and affect the service life of the flexible OLED display substrate.

An embodiment of the present disclosure provides a display substrate, which includes multiple pixel island areas separated from each other, multiple hole areas and a connection bridge area connecting the multiple pixel island areas. The hole area includes a base substrate and an encapsulation layer. The base substrate is provided with an aperture, a barrier structure is provided on a side of the base substrate close to the aperture, and the encapsulation layer covers a side of the base substrate facing the aperture.

Technical solutions of the embodiments of the present disclosure are exemplarily illustrated below with reference to the accompanying drawings.

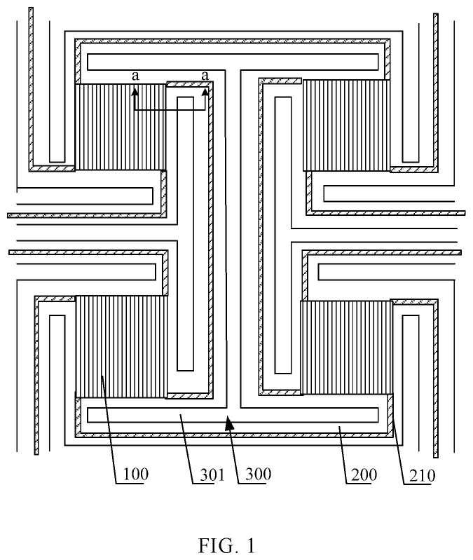

FIG. 1 is a schematic plan view of a display substrate according to an exemplary embodiment of the present disclosure. In some exemplary embodiments, as shown in FIG. 1, a main body structure of a display substrate 1 includes multiple pixel island areas 100 separated from each other, multiple hole areas 300 and a connection bridge area 200 connecting the multiple pixel island areas 100. The multiple pixel island areas 100, the multiple hole areas 300 and the connection bridge area 200 are provided on a base substrate which is a flexible base substrate. The pixel island areas 100 are configured to display an image, the connection bridge area 200 is used for routing and transmitting tension and the hole areas 300 are configured to provide a deformation space during stretching. A pixel island area 100 includes one or more pixel units, a pixel unit may include three (red, green and blue) or four (red, green, blue and white) light emitting units that emit light of different colors, and the pixel island area may be rectangular or square in a plane parallel to the base substrate. The hole area 300 on the periphery of the pixel island area 100 is composed of multiple apertures 301 penetrating the base substrate, wherein the aperture 301 are L-shaped, or in a shape of multiple connected “L” shapes, such as [symbol] -shaped and T-shaped, wherein a width of an aperture 301 ranges from 10 microns to 500 microns. The connection bridge area 200 is located between a pixel island area 100 and a hole area 300, or between adjacent hole areas 300, connected with the adjacent pixel island area 100. Namely, the connection bridge area 200 surrounds the pixel island area 100 and the hole area 300. The connection bridge area 200 may be L-shaped, or multiple L-shaped connected shapes, such as [symbol] -shaped and T-shaped. A width of the connection bridge area 200 ranges from 10 microns to 500 microns. The light emitting units of the multiple pixel island areas 100 are in signal communication through a connection line 210 in the connection bridge area 200.

FIG. 2 is a cross-sectional view at the position a-a in FIG. 1. In some exemplary embodiments, the pixel island area 100 includes a drive structure layer, a light emitting structure layer provided on the drive structure layer and an encapsulation layer 24 covering the light emitting structure layer. The drive structure layer mainly includes a pixel drive circuit formed by multiple thin film transistors (TFTs). As shown in FIG. 2, a main body structure of the drive structure layer includes a first insulation layer 11 provided on a base substrate 10, an active layer 12 provided on the first insulation layer 11, a second insulation layer 13 provided on the active layer 13, a first gate metal layer 14 provided on the second insulation layer 13, a third insulation layer 15 provided on the first gate metal layer 14, a second gate metal layer 16 provided on the third insulation layer 15, a fourth insulation layer 17 provided on the second gate metal layer 16, and a source and drain metal layer 18 provided on the fourth insulation layer 17. The first insulation layer 11, the second insulation layer 13, the third insulation layer 15 and the fourth insulation layer 17 may be inorganic insulation layers. The drive structure layer of the pixel island area 100 is covered with a planarization layer 19 on which the light emitting structure layer is provided. The light emitting structure layer includes an anode 20, a pixel definition layer 21 defining a pixel opening area, an organic light emitting layer 22 provided on the pixel definition layer 21 and a cathode 23 provided on the organic light emitting layer 22. The encapsulation layer 24 covers the light emitting structure layer. The base substrate 10 of the pixel island area 100 includes a first flexible base substrate layer 101, a first barrier layer 102, a buffer layer 103 and a second barrier layer 104 and a second flexible base substrate layer 105 which are stacked.

In some exemplary embodiments, as shown in FIG. 2, the main body structure of the connection bridge area 200 includes a composite insulation layer, a connection line (not shown), an isolation dam 25, the organic light emitting layer 22 and the cathode 23, and the encapsulation layer 24 provided on the base substrate 10. The composite insulation layer of the connection bridge area 200 includes the first insulation layer 11, the second insulation layer 13, the third insulation layer 15 and the fourth insulation layer 17 which are stacked. The isolation dam 25 and the connection line (not shown) are provided on the composite insulation layer, and the organic light emitting layer 22, the cathode 23 and the encapsulation layer 24 cover the isolation dam 25. A cross section of the isolation dam 25 has a trapezoidal shape with a narrower upper bottom and a wider lower bottom. In an example, in a plane perpendicular to the base substrate 10, a height of the isolation dam 25 ranges from about 25 microns to 100 microns, a width of the upper bottom ranges from about 20 microns to 60 microns, and a width of the lower bottom ranges from about 20 microns to 60 microns. The base substrate 10 of the connection bridge area 200 includes the first flexible base substrate layer 101, the first barrier layer 102, the buffer layer 103 and the second barrier layer 104 and the second flexible base substrate layer 105 which are stacked.

In some exemplary embodiments, as shown in FIG. 2, the hole area 300 mainly includes the composite insulation layer, the organic light emitting layer 22 and the cathode 23 and the encapsulation layer 24 provided on the base substrate 10. An aperture 301 is provided on the base substrate 10, and the aperture 301 penetrates through the composite insulation layer and the base substrate 10. The composite insulation layer includes a first end face facing the aperture 301 and the first end face separates the organic light emitting layer 22 and the cathode 23. The encapsulation layer 24 covers the cathode 23, the first end face and a side of the base substrate 10 close to the aperture 301. The composite insulation layer of the hole area 300 includes the first insulation layer 11, the second insulation layer 13, the third insulation layer 15 and the fourth insulation layer 17 which are stacked. The base substrate 10 of the hole area 300 includes the first flexible base substrate layer 101, the first barrier layer 102, the buffer layer 103, the second barrier layer 104 and the second flexible base substrate layer 105 which are stacked. With respect to surfaces of the first barrier layer 102 and the second barrier layer 104 facing the aperture 301, a surface of the buffer layer 103 facing the aperture 301 is recessed in a direction away from the aperture 301, forming a barrier groove 106 with a notch facing the aperture 301. In other words, the first barrier layer 102 includes a second end face facing the aperture 301, the buffer layer 103 includes a third end face facing the aperture 301, and the second barrier layer 104 includes a fourth end face facing the aperture 301. In a direction parallel to the base substrate 10, a distance between the second end face and the first end face is smaller than a distance between the third end face and the first end face, a distance between the fourth end face and the first end face is smaller than the distance between the third end face and the first end face, and the distance between the second end face may be equal to or different from the first end face and the distance between the fourth end face and the first end face. In one example, the second end face is flush with the fourth end face, and in another example, the second end face and the fourth end face are flush with the first end face. Opposite sides of the first barrier layer 102 and the second barrier layer 104 form sidewalls of the barrier groove 106, and the third end surface forms a groove bottom of the barrier groove 106. A thickness of the encapsulation layer 24 inside the barrier groove 106 is less than a thickness of the encapsulation layer 24 outside the barrier groove 106, or the encapsulation layer 24 inside the barrier groove 106 is discontinuous (there is a fracture position). The encapsulation layer 24 inside the barrier groove 106 forms a fracture zone, and the thickness of the encapsulation layer 24 is a thickness in the direction perpendicular to a wall surface to which the encapsulation layer 24 is attached. For example, in the barrier groove 106, the thickness of the encapsulation layer 24 attached to the first barrier layer 102 is a thickness of the encapsulation layer 24 in the direction perpendicular to a surface of the first barrier layer 102 facing the second barrier layer 104, which is also a thickness in the direction perpendicular to the base substrate 10. The thickness of the encapsulation layer 24 attached to the second barrier layer 104 is a thickness of the encapsulation layer 24 in the direction perpendicular to a surface of the second barrier layer 104 facing the first barrier layer 102, which is also the thickness in the direction perpendicular to the base substrate 10. The thickness of the encapsulation layer 24 attached to the third end face of the buffer layer 103 is a thickness of the encapsulation layer 24 in the direction perpendicular to the third end face. Outside the barrier groove 106, the thickness of the encapsulation layer 24 attached to a side of the composite insulation layer facing the aperture 301 is the thickness of the encapsulation layer 24 in the direction perpendicular to a surface of the composite insulation layer facing the aperture 301. Namely, the thickness of the encapsulation layer 24 attached to the first end face is the thickness of the encapsulation layer 24 in the direction perpendicular to the first end face. The thickness of the encapsulation layer 24 inside the barrier groove 106 being smaller than the thickness of the encapsulation layer 24 outside the barrier groove 106 may refer to that the thickness of the encapsulation layer 24 at some positions inside the barrier groove 106 is smaller than the thickness of the encapsulation layer 24 outside the barrier groove 106. The encapsulation layer 24 in the fracture area is prone to breakage because it is thin or even discontinuous.

In some exemplary embodiments, an inorganic encapsulation thin film is only deposited in a small amount or is not deposited at some positions in the barrier groove 106, and the encapsulation layer 24 inside the barrier groove 106 is thus thinner, even discontinuous and prone to breakage. That is to say, the encapsulation layer 24 inside the barrier groove 106 forms the fracture area, so that the encapsulation layer 24 located at a side of the barrier groove 106 close to the second flexible base substrate 105 can be effectively prevented from being torn and broken during a process of separating the base substrate 10 from the rigid substrate, thereby enhancing the reliability of encapsulation of the encapsulation layer 24 without affecting the tensile property of the device. That is, the barrier groove 106 is configured to form the fracture area of the encapsulation layer 24 and the barrier groove 106 forms a barrier structure.

In some exemplary embodiments, a depth L1 of the barrier groove 106 ranges from about 0.2 microns to 2 microns, and a width D1 of the barrier groove 106 ranges from about 0.2 microns to 2 microns. In other words, the depth of the barrier groove 106 refers to a distance from the notch to the bottom of the groove and the width of the barrier groove 106 refers to a distance between two opposite sidewalls. The barrier groove 106 with a larger depth and a smaller width facilitates restricting an inorganic packaging material into the barrier groove 106, thereby reducing amount of the inorganic packaging material deposited within the barrier groove 106.

In some exemplary embodiments, the first flexible base substrate layer 101 includes a fifth end face facing the aperture 301, and the second flexible base substrate layer 105 includes a sixth end face facing the aperture 301. In the direction parallel to the base substrate 10, a distance between the fifth end face and the first end face is larger than the distance between the second end face and the first end face, larger than the distance between the fourth end face and the first end face, and smaller than the distance between the third end face and the first end face. A distance between the sixth end face and the first end face is larger than the distance between the second end face and the first end face, larger than the distance between the fourth end face and the first end face, and smaller than the distance between the third end face and the first end face. The fifth end face is flush with the sixth end face.

A structure of the display substrate will be described below through an example of a preparation process of the display substrate. A “patterning process” mentioned in embodiments of the present disclosure includes processes such as film layer deposition, photoresist coating, mask exposure, development, etching, and photoresist stripping. The deposition may be any one or more of sputtering, evaporation, and chemical vapor deposition. The coating may be any one or more of spray coating and spin coating. The etching may be any one or more of dry etching and wet etching. A “thin film” refers to a thin film layer prepared from a material on a base substrate by a process of deposition or coating. If a patterning process is not needed by a “thin film” throughout a whole preparation process, the “thin film” may also be referred to as a “layer”. When a patterning process is also needed by a “thin film” throughout a whole preparation process, the thin film is referred to as a “thin film” before the patterning process and referred to as a “layer” after the patterning process. The “layer” after the patterning process includes at least one “pattern”. “A and B are provided in a same layer” mentioned in the present disclosure means that A and B are simultaneously formed by a same patterning process. “An orthographic projection of A contains an orthographic projection of B” refers to that the orthographic projection of B falls within a range of the orthographic projection of A or the orthographic projection of A covers the orthographic projection of B.

(1) A base substrate is prepared on a rigid substrate 2.

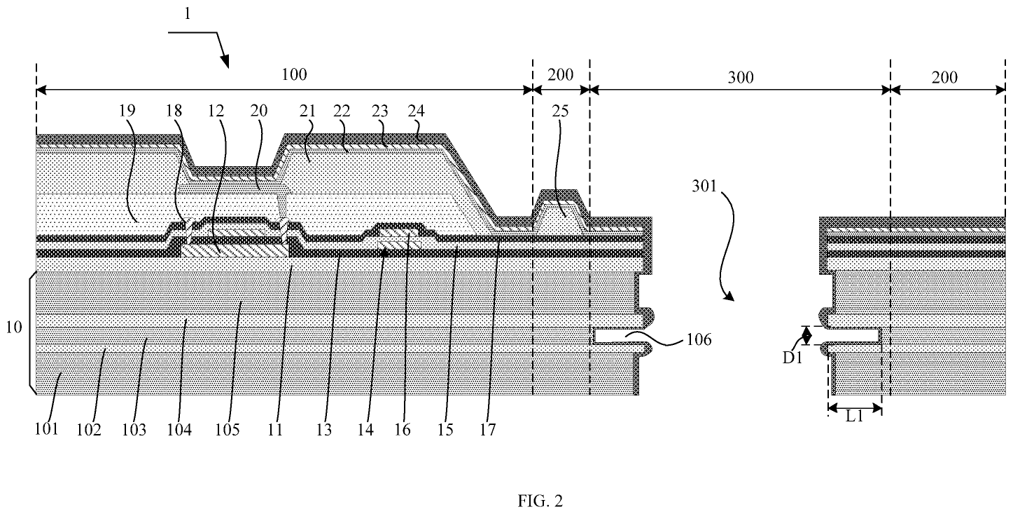

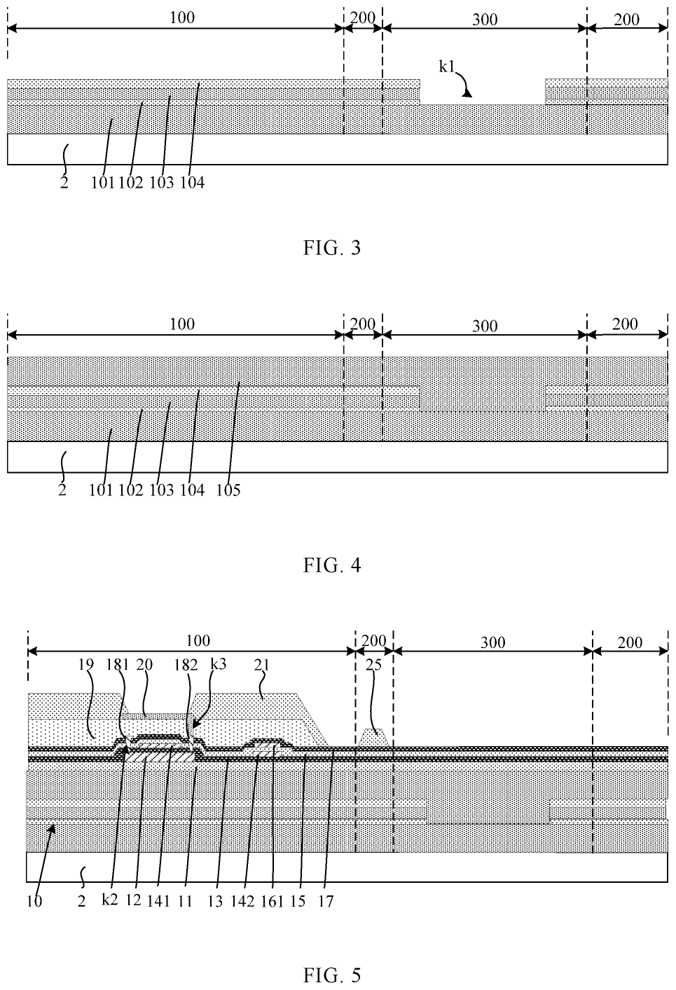

A first flexible base substrate thin film is coated on the rigid substrate 2 and cured into a film to form a first flexible base substrate layer 101, as shown in FIG. 3. In an exemplary embodiment, a material of the first flexible base substrate layer 101 may be polyimide, a thickness of the first flexible base substrate layer ranges from 2 microns to 10 microns and the rigid substrate may be made of a glass substrate. FIG. 3 is a schematic diagram of a structure after a first opening is formed according to an exemplary embodiment of the present disclosure.

Subsequently, a first barrier thin film, a buffer thin film, and a second barrier thin film are deposited on the first flexible base substrate layer 101, and the second barrier thin film is patterned by a patterning process, thereby forming patterns of the first barrier layer 102, the buffer layer 103, and the second barrier layer 104 which are stacked and the first opening k1, as shown in FIG. 3. The first barrier layer 102, the buffer layer 103, and the second barrier layer 104 cover the first flexible base substrate layer 101 in the pixel island area 100 and the connection bridge area 200. The first opening k1 is provided in the hole area 300 and exposes the first flexible base substrate layer 101. The first barrier layer 102 includes a second end face facing the first opening k1 and the second barrier layer 104 includes a fourth end face facing the first opening k1, wherein the second end face is flush with the fourth end face. After the patterning process, the pixel island area 100 and the connection bridge area 200 include the first flexible base substrate layer 101 and the first barrier layer 102, the buffer layer 103 and the second barrier layer 104 stacked on the first flexible base substrate layer 101. The hole area 300 includes the first flexible base substrate layer 101, and the first barrier layer 102, the buffer layer 103, and the second barrier layer 104 which are stacked on the first flexible base substrate layer 101 and the first opening k1. The first barrier layer 102, the buffer layer 103, and a surface of the second barrier layer 104 facing the first opening k1 are flush. In an exemplary embodiment, materials of the first barrier layer 102, the buffer layer 103, and the second barrier layer 104 may be inorganic materials such as silicon oxide (SiOx), silicon nitride (SiNx), silicon oxynitride (Al₂O₃), or silicon oxynitride (SiOₓNₓ), and the materials of the first barrier layer and the second barrier layer may be the same, but different from the material of the buffer layer. The first barrier layer 102, the buffer layer 103, and the second barrier layer 104 may be configured to improve the water oxygen resistance of the base substrate.

Subsequently, a second flexible base substrate thin film is coated on the base substrate on which the above patterns are formed, and cured into a film to form a second flexible base substrate layer 105, as shown in FIG. 4. The second flexible base substrate layer 105 fills the first opening k1 and covers the second barrier layer 104 of the pixel island area 100, the connection bridge area 200 and the hole area 300. In an exemplary embodiment, a material of the second flexible base substrate layer 105 may be polyimide. A thickness of the second flexible base substrate layer ranges from 2 microns to 10 microns. FIG. 4 is a schematic diagram of a structure after the second flexible base substrate layer is formed according to an exemplary embodiment of the present disclosure.

(2) Patterns of a drive structure layer and a connection line are prepared on the base substrate. The pattern of the drive structure layer is located in the pixel island area, and the pattern of the connection line is located in the connection bridge area. FIG. 5 is a schematic diagram of a structure after a pixel definition layer and an isolation dam are formed according to an exemplary embodiment of the present disclosure. In an exemplary embodiment, the preparation process of the drive structure layer may include:

A first inorganic insulation thin film and an active layer thin film are sequentially deposited on the base substrate 10, and the active layer thin film is patterned through a patterning process to form a first insulation layer 11 covering the entire base substrate 10 and a pattern of an active layer 12 provided on the first insulation layer 11. The pattern of the active layer 12 is formed in the pixel island area 100. After this patterning process, the connection bridge area 200 and the hole area 300 include the first insulation layer 11 provided on the base substrate 10, and the active layer thin film of the connection bridge area 200 and the hole area 300 are etched away.

Then, a second inorganic insulation thin film and a first metal thin film are sequentially deposited and the first metal thin film is patterned by a patterning process to form a second insulation layer 13 covering the pattern of the active layer 12 and a pattern of a first gate metal layer provided on the second insulation layer 13. The pattern of the first gate metal layer is formed in the pixel island area 100 and includes at least a gate electrode 141 and a first capacitor electrode 142. After this patterning process, the connection bridge area 200 and the hole area 300 include the first insulation layer 11 and the second insulation layer 13 which are stacked on the base substrate 10, and the first metal thin film of the connection bridge area 200 and the hole area 300 are etched away.

Then, a third inorganic insulation thin film and a second metal thin film are sequentially deposited and the second metal thin film is patterned by a patterning process to form a third insulation layer 15 covering the first gate metal layer and a pattern of a second gate metal layer provided on the third insulation layer 15. The pattern of the second gate metal layer is formed in the pixel island area 100 and includes at least a second capacitor electrode 161. A position of the second capacitor electrode 161 corresponds to that of the first capacitor electrode 142. An orthographic projection of the second capacitor electrode 161 on the base substrate 10 at least partially overlaps with an orthographic projection of the first capacitor electrode 142 on the base substrate 10. After this patterning process, the connection bridge area 200 and the hole area 300 include the first insulation layer 11, the second insulation layer 13 and the third insulation layer 15 which are stacked on the base substrate 10, and the second metal thin film of the connection bridge area 200 and the hole area 300 are etched away.

Then, a fourth inorganic insulation thin film is deposited and patterned by a patterning process to form a pattern of a fourth insulation layer 17 covering the second gate metal layer. The fourth insulation layer 17 is provided with two first via holes k2, and the fourth insulation layer 17, the third insulation layer 15 and the second insulation layer 13 in the two first via holes k2 are etched away, exposing a surface of the active layer 13. After this patterning process, the connection bridge area 200 and the hole area 300 include the first insulation layer 11, the second insulation layer 13, the third insulation layer 15 and the fourth insulation layer 17 which are stacked on the base substrate 10.

Subsequently, a third metal thin film is deposited and patterned through the patterning process to form a pattern of a source-drain metal layer on the fourth insulation layer 17, and the pattern of the source-drain metal layer includes a source electrode 181 and a drain electrode 182 located in the pixel island area 100, and the connection line (not shown in the drawings) located in the connection bridge area 200. The source electrode 181 and the drain electrode 182 are electrically connected with the active layer 12 through the via holes k2. After this patterning process, the film layer structure of the hole area 300 remains unchanged.

So far, the preparation of the drive structure layer of the pixel island area and the connection line of the connection bridge area on the base substrate has is completed. In the drive structure layer of the pixel island area, the active layer, the gate electrode, the source electrode and the drain electrode form a thin film transistor, wherein the first capacitor electrode and the second capacitor electrode form a first storage capacitor. The connection bridge area and the hold area include the composite insulation layer provided on the base substrate, and the composite insulation layer includes the first insulation layer, the second insulation layer, the third insulation layer, and the fourth insulation layer which are stacked. The connection bridge area further includes the connection line provided on the composite insulation layer.

In an exemplary embodiment, the first insulation layer, the second insulation layer, the third insulation layer, and the fourth insulation layer may be made of any one or more of silicon oxide (SiOx), silicon nitride (SiNx), and silicon oxynitride (SiON), and each may be of a single layer, multiple layers, or a composite layer. The first insulation layer is referred to as the buffer layer configured to improve the water oxygen resistance of the base substrate, the second and the third insulation layers are referred to as gate insulation (GI) layers, and the fourth insulation layer is referred to as a interlayer dielectric (ILD) layer. The first metal thin film, the second metal thin film and the third metal thin film may be made of a metal material, such as any one or more of silver (Ag), copper (Cu), aluminum (Al), titanium (Ti) and molybdenum (Mo), or an alloy material of the above metals, such as aluminum-neodymium alloy (AlNd) or molybdenum-niobium alloy (MoNb), which may be in a single-layer structure or a multi-layer composite structure, such as Ti/Al/Ti. The active layer may be made of various materials, such as amorphous indium gallium zinc oxide (α-IGZO), zinc oxynitride (ZnON), indium zinc tin oxide (IZTO), amorphous silicon (α-Si), polycrystalline silicon (p-Si), hexathiophene and polythiophene. That is, the present disclosure is applicable to transistors manufactured based on oxide technology, silicon technology, and organic substance technology.

(3) A planarization thin film of an organic material is coated on the base substrate on which the above patterns are formed, and a planarization layer 19 is formed in the pixel island area 100 by masking, exposure and development processes, and a pattern of a second via hole k3 is formed in the planarization layer 19. The second via hole k3 is formed in the pixel island area 100, and the planarization layer 19 in the second via hole k3 is developed away to expose a surface of the drain electrode 182 of the thin film transistor. After this process, film layer structures of the connection bridge area 200 and the hole area 300 remain unchanged.

(4) A transparent conductive thin film is deposited on the base substrate on which the above patterns are formed and patterned by a patterning process to form a pattern of an anode 20. The anode 20 is formed on the planarization layer 19 of the pixel island area 100 and is connected with the drain electrode 182 of the thin film transistor through the second via hole k3. After this patterning process, the film layer structures of the connection bridge area 200 and the hole area 300 remain unchanged. In an exemplary embodiment, the transparent conductive thin film may be made of indium tin oxide (ITO) or indium zinc oxide (IZO).

(5) A pixel definition thin film is coated on the base substrate on which the above patterns are formed, and patterns of the pixel definition layer (PDL) 21 and the isolation dam 25 are formed by masking, exposure and development processes. The pixel definition layer 21 is formed in the pixel island area 100 and the isolation dam 25 is formed in the connection bridge area 200. In a plane perpendicular to the base substrate, a cross section of the isolation dam 25 has a trapezoidal shape with a narrower upper bottom and a wider lower bottom. The pixel definition layer 21 is provided with pixel openings, and the pixel definition layer 21 within the pixel opening is developed away to expose a surface of the anode 20. In an exemplary embodiment, the pixel definition layer may be made of polyimide, acrylic or polyethylene terephthalate. In some exemplary embodiments, the isolation dam 25 may be formed together with the planarization layer 19 using a single patterning process. That is, the isolation dam 25 and the planarization layer 19 may be provided in the same layer.

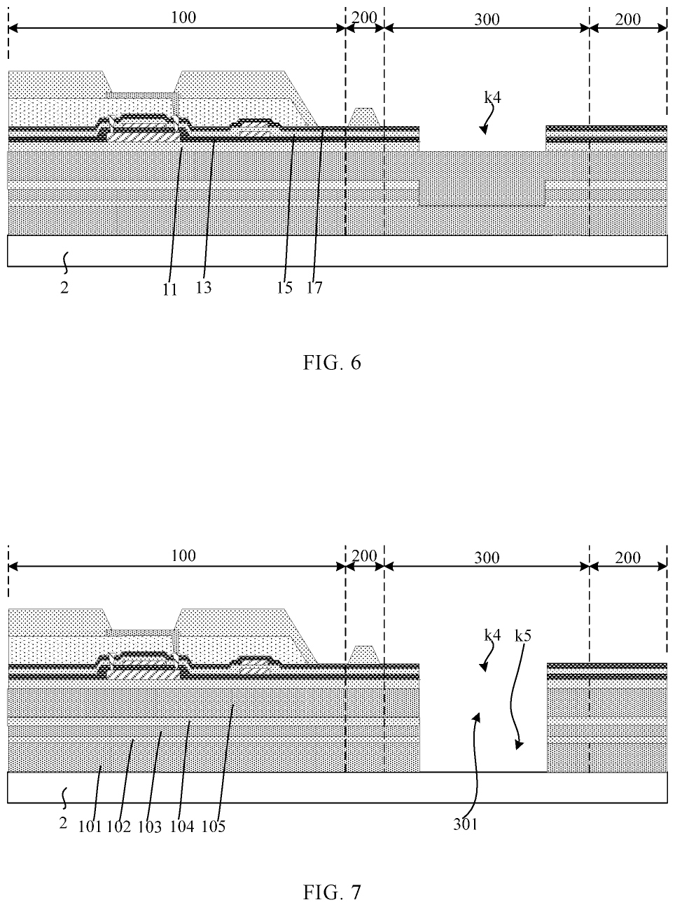

(6) The composite insulation layer is patterned by a patterning process on the base substrate on which the above patterns are formed, and a pattern of a second opening k4 is formed, as shown in FIG. 6. The second opening k4 is formed in the hole area 300, the second opening k4 corresponds to the position of an aperture, and the first insulation layer 11, the second insulation layer 13, the third insulation layer 15, and the fourth insulation layer 17 in the second opening k4 are etched away, that is, the composite insulation layer is etched away to expose the second flexible base substrate layer 105. The composite insulation layer includes a first end face facing the second opening k4. In an example, the first end face is flush with the second end face, and the first end face is flush with the fourth end face. After this patterning process, the film layer structures of the pixel island area 100 and the connection bridge area 200 remain unchanged. After the second opening k4 is formed, the photoresist mask for forming the second opening k4 is not lifted off. FIG. 6 is a schematic diagram of a structure after the second opening is formed according to an exemplary embodiment of the present disclosure.

(7) The second flexible base substrate layer 105 is etched on the base substrate on which the above patterns are formed and a pattern of a third opening k5 is formed, as shown in FIG. 7. The third opening k5 is formed in the hole area 300, the third opening k5 corresponds to the positions of the first opening and the second opening k4, and an orthographic projection of the third opening k5 on the rigid substrate 2 coincides with an orthographic projection of the first opening on the rigid substrate 2. After this patterning process, the second flexible base substrate layer 105 and the first flexible base substrate layer 101 within the third opening k5 are etched away to expose the rigid substrate 2. The film layer structures of the pixel island area 100 and the connection bridge area 200 remain unchanged. The third opening k5 and the second opening k4 form the aperture 301 of the hole area 300. After the third opening k5 is formed, the photoresist mask for forming the second opening k4 is not lifted off. FIG. 7 is a schematic diagram of a structure after the third opening is formed according to an exemplary embodiment of the present disclosure.

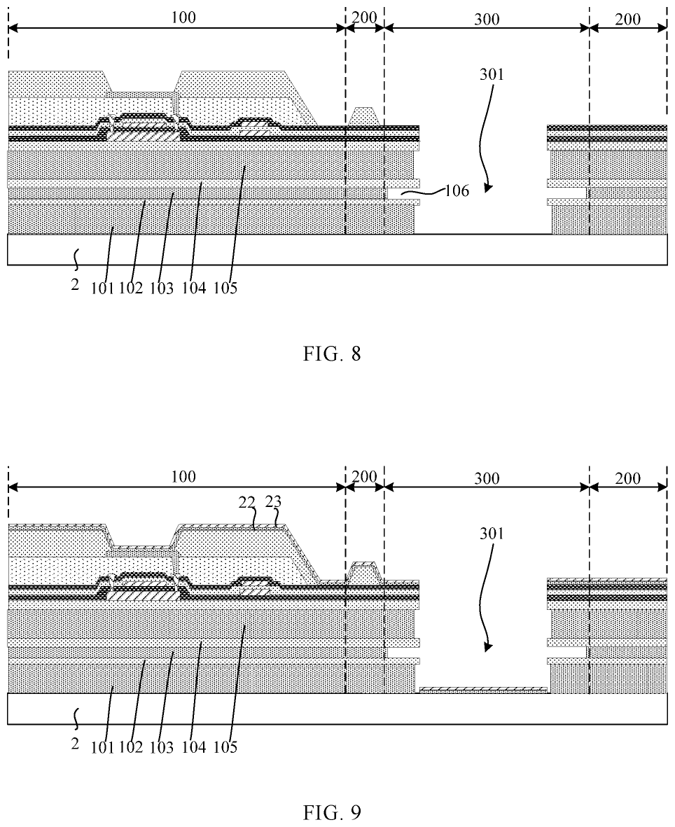

(8) The buffer layer 103 is etched on the base substrate on which the above patterns are formed. As shown in FIG. 8, the buffer layer 103 includes a third end face facing the aperture 301. In the direction parallel to the base substrate 10, a distance between the third end face and the first end face is larger than a distance between the second end face and the fourth end face. The barrier groove 106 is formed between the first barrier layer 102, the buffer layer 103, and the second barrier layer 104. In a plane perpendicular to the base substrate, the barrier groove 106 has a depth of about 0.2 microns to 2 microns and the barrier groove 106 has a width of about 0.2 microns to 2 microns. In some embodiments, the first barrier layer 102 and the second barrier layer 104 may be etched during etching the buffer layer 103, but an etching rate of the buffer layer 103 is greater than an etching rate of the first barrier layer 102 and the second barrier layer 104. For example, a material of the buffer layer 103 may be selected as silicon nitride (SiNx), and materials of the first barrier layer 102 and the second barrier layer 104 may be selected as silicon oxide (SiOx). An etching rate of the silicon nitride (SiNx) by the etching gas is greater than an etching rate of the silicon oxide (SiOx) by the etching gas by selecting a dry etching method and a suitable etching gas composition. In some exemplary embodiments, the first flexible base substrate layer 101 and the second flexible base substrate layer 105 are also etched during etching the buffer layer 103, but the etching rate is less than that of the buffer layer 103. In other words, the first flexible base substrate layer 101 includes a fifth end face facing the aperture 301, and the second flexible base substrate layer 105 includes a sixth end face facing the aperture 301, wherein the fifth end face is flush with the sixth end face. In the direction parallel to the base substrate, a distance between the fifth and sixth end faces and the first end face is larger than a distance between the second and fourth end faces and the first end face and less than the distance between the third end face and the first end face. FIG. 8 is a schematic diagram of a structure after the barrier groove is formed according to an exemplary embodiment of the present disclosure.

(9) An organic light emitting material and a cathode metal thin film are sequentially evaporated on the base substrate on which the above patterns are formed, and patterns of an organic light emitting layer 22 and a cathode 23. In the pixel island area 100, the organic light emitting layer 22 is connected with the anode 20 in the pixel opening area, and the cathode 23 is provided on the organic light emitting layer 22. In the connection bridge area 200, the organic light emitting layer 22 and the cathode 23 cover the isolation dam 25. In the hole area 300, the organic light emitting layer 22 and the cathode 23 are separated by a side of the composite insulation layer facing the aperture 301 i.e. by the first end face. The organic light emitting layer mainly includes a light emitting layer (EML). In actual implementation, the organic light emitting layer may include a hole injection layer, a hole transport layer, a light emitting layer, an electron transporting layer, and an electron injection layer provided sequentially to improve an efficiency of injecting electrons and holes into the light emitting layer. The cathode may be made of one of a metal material such as magnesium (Mg), argentum (Ag), aluminum (Al), copper (Cu), lithium (Li), or an alloy of one or more of the above metals. FIG. 9 is a schematic diagram of a structure after the organic light emitting layer and cathode are formed according to an exemplary embodiment of the present disclosure.

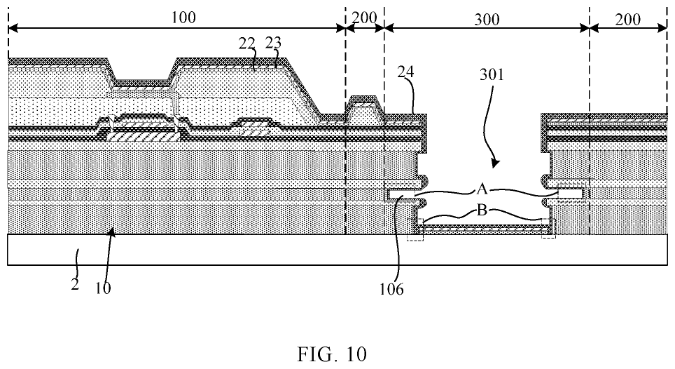

(9) An inorganic encapsulation thin film is deposited on the base substrate on which the above patterns are formed, and as shown in FIG. 10, an encapsulation layer 24 covering the pixel island area 100, the connection bridge area 200, and the hole area 300 is formed. In the pixel island area 100, the encapsulation layer 24 covers the cathode 23. In the connection bridge area 200, the encapsulation layer 24 is provided on the cathode 23. In the hole area 300, the encapsulation layer 24 is provided on the cathode 23 and wraps the composite insulation layer and a side of the base substrate 10 close to the aperture 301. Since the barrier groove is deep and has a small opening, the amount of inorganic packaging material layer deposited in the barrier groove 106 is small, the encapsulation layer is thin and even discontinuous, and is prone to breakage, and the encapsulation layer 24 formed in the barrier groove 106 constitutes a fracture zone. In an exemplary embodiment, the encapsulation layer 24 is prepared by chemical vapor deposition and atomic layer deposition. A material of the encapsulation layer 24 includes aluminum oxide (Al₂O₃), silicon oxide (SiOₓ) or silicon nitride (SiₓN_{y}), and a thickness of the encapsulation layer 24 ranges from about 0.5 microns to 2 microns. FIG. 10 is a schematic diagram of a structure after the encapsulation layer is formed according to an exemplary embodiment of the present disclosure.

(10) A display substrate 1 is formed by lifting off the base substrate 10 from the rigid substrate 2 using a laser process, as shown in FIG. 2. In this way, that is, the preparation of the display substrate 1 is completed, and the prepared display substrate 1 includes:

the base substrate 10 including the first flexible base substrate layer 101, the first barrier layer 102, the buffer layer 103, the second barrier layer 104, and the second flexible base substrate layer 105;

the first insulation layer 11 provided on the base substrate 10;

the active layer 12 provided on the first insulation layer 11;

the second insulation layer 13 provided on the active layer 12;

the first gate metal layer 14 provided on the second insulation layer 13, wherein the first gate metal layer 14 is provided in the pixel island area 100 and includes at least the gate electrode 141 and the first capacitor electrode 142;

the third insulation layer 15 covering the first gate metal layer 14;

the second gate metal layer 16 provided on the third insulation layer 15, wherein the second gate metal layer 16 is provided in the pixel island area 100 and includes at least the second capacitor electrode 161, and the position of the second capacitor electrode 161 corresponding to the position of the first capacitor electrode 142;

the fourth insulation layer 17 covering the second gate metal layer 16, wherein the first via holes are provided on the fourth insulation layer 17, the first via holes are provided in the pixel island area 100, the first via holes expose the active layer 12, the first insulation layer 11, the second insulation layer 13, the third insulation layer 15 and the fourth insulation layer 17 form the composite insulation layer of the connection bridge area 200 and the hole area 300, and the composite insulation layer is an inorganic insulation layer;

the source-drain metal layer 18 provided on the fourth insulation layer 17, wherein the source-drain metal layer 18 at least includes the source electrode 181 and the drain electrode 182 provided in the pixel island area 100, and the connection line 210 in the connection bridge area 200, the source electrode 181 and the drain electrode 182 are connected with the active layer 12 through the first via holes, respectively, and a conductive channel is formed between the source electrode 181 and the drain electrode 182.

the planarization layer 19 covering the aforementioned structures, wherein the planarization layer 19 is provided with the second via hole exposing the drain electrode 182;

the anode 20 provided on the planarization layer 19, wherein the anode 20 is connected with the drain electrode 182 through the second via hole;

the pixel definition layer 21 and the isolation dam 25, wherein the pixel definition layer 21 is located in the pixel island area 100, the pixel definition layer 21 is provided on the anode 20, the pixel opening is provided on the pixel definition layer 21 and exposes the anode 20, and the isolation dam 25 is provided in the connection bridge area 200;

the organic light emitting layer 22 and the cathode 23 covering the aforementioned structures, wherein the organic light emitting layer 22 of the pixel island area 100 is provided in the pixel opening area and the cathode 23 is provided on the organic light emitting layer 22; the organic light emitting layer 22 and the cathode 23 of the connection bridge area 200 cover the isolation dam 25; the organic light emitting layer 22 and the cathode 23 of the hole area 300 are separated on the sidewall of the composite insulation layer facing the aperture;

the encapsulation layer 24 covering the aforementioned structures, wherein the encapsulation layer 24 covers the cathode 13 in the pixel island area 100; the encapsulation layer 24 is provided on the cathode 23 in the connection bridge area 200; the encapsulation layer 24 is provided on the cathode 23 and wraps the composite insulation layer and a side of the base substrate 10 close to the aperture 301 in the hole area 300;

wherein the composite insulation layer includes the first end face facing the aperture 301, the first barrier layer 102 includes the second end face facing the aperture 301, the buffer layer 103 includes the third end face facing the aperture 301, and the second barrier layer 104 includes the fourth end face facing the aperture 301;

In the direction parallel to the base substrate, the distance between the second end face and the first end face is smaller than the distance between the third end face and the first end face, the distance between the fourth end face and the first end face is smaller than the distance between the third end face and the first end face, the third end face is provided as the groove bottom of the barrier groove 106, and the opposite surfaces of the first barrier layer 102 and the second barrier layer 104 are provided as sidewalls of the barrier groove 106.

In the above embodiments, the isolation dam and the planarization layer may be provided in the same layer, or the isolation dam may include a first support layer and a second support layer which are stacked, wherein the first support layer and the planarization layer are formed by a same patterning process, and the second support layer and the pixel definition layer are formed by same patterning process.

As shown in FIG. 10, since the barrier groove 106 is deep and the opening (the width of the barrier groove) is small, which is equivalent to the thickness of the encapsulation layer 24, the amount of the inorganic packaging material deposited in the barrier groove 106 is very small, the encapsulation layer 24 is thin, and even discontinuous, thus a fracture zone A of the encapsulation layer 24 is formed. Although the sidewall of the base substrate 10 facing the aperture 301 and the encapsulation layer 24 at the transition position B of the rigid substrate 2 is thick, there is a lift-off risk during a process of lifting off the base substrate 10 from the rigid substrate 2, but the lift-off will be cut off in the fracture zone A, preventing the encapsulation layer 24 from being lifted off continuously, thereby improving the reliability of the encapsulation layer and prolonging the service life of the display substrate.

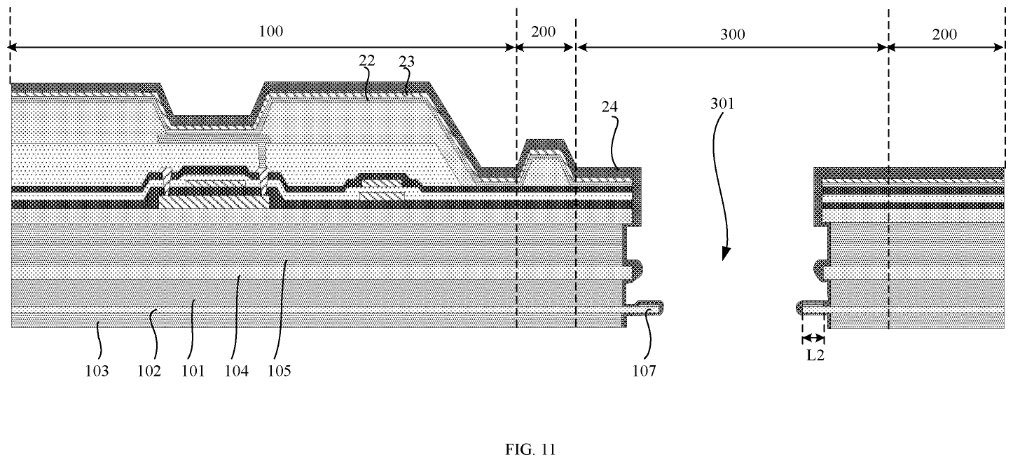

FIG. 11 is a schematic diagram of a structure of another display substrate according to an exemplary embodiment of the present disclosure. In some exemplary embodiments, the exemplary embodiment of the present disclosure further provides another display substrate. As shown in FIG. 11, the base substrate 10 of the hole area 300 includes the buffer layer 103, the first barrier layer 102, the first flexible base substrate layer 101, the second barrier layer 104 and the second flexible base substrate layer 105 which are stacked. The encapsulation layer 24 of the hole area 300 covers the composite insulation layer and the base substrate 10. The first barrier layer 102 extends into the aperture 301, that is, the first barrier layer 102 protrudes in the direction of the second end face facing the aperture 301 towards the aperture 301 and goes beyond the first end face of the composite insulation layer toward the aperture 301, forming a barrier eave 107. The fracture area of the encapsulation layer 24 is formed between the barrier eave 107 and the buffer layer 103, and the encapsulation layer in the fracture area is thin or discontinuous, and the barrier eave 107 forms a barrier structure. Since the barrier eave extends into the aperture 301, a side of the barrier eave 107 facing away from the buffer layer 103 is provided with the organic light emitting layer 22 and the cathode 23 separated by the barrier eave 107. In other words, the organic light emitting layer 22 and the cathode 23 are separated not only at the first end face but also at the second end face.

In an example, a length L2 of the barrier eave 107 ranges from about 0.2 microns to 2 microns, a thickness of the buffer layer 103 ranges from about 0.2 microns to 2 microns, and the length of the barrier eave 107 may be understood as a distance by which the second end face protrudes beyond the first end face. Thus, during the preparation process, a spacing between the barrier eave 107 and the rigid substrate 2 ranges from about 0.2 microns to 2 microns, forming a deeper and narrower groove structure, which can restrict deposition of the inorganic encapsulation thin film under the barrier eave 107, thereby forming the fracture zone of the encapsulation layer 24.

The technical solution of the display substrate of this exemplary embodiment is exemplarily described below by an example of the preparation process of the display substrate. The preparation process of the display substrate may use the following two preparation processes.

In an embodiment, the first preparation process:

(1) A base substrate 10 is prepared on a rigid substrate 2.

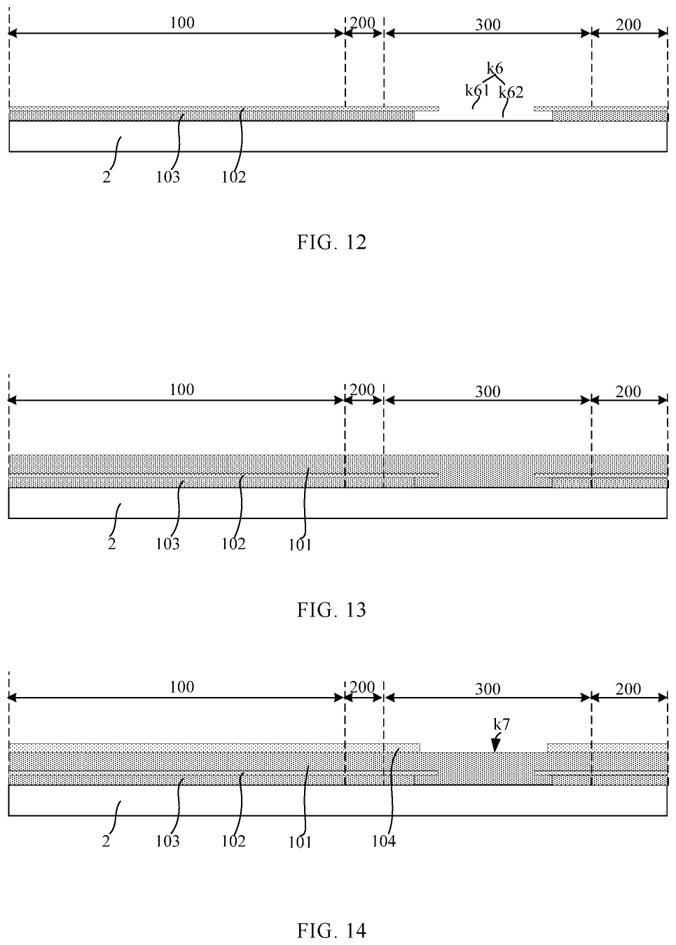

A buffer thin film and a first barrier thin film are deposited on the rigid substrate 2, and the first barrier thin film is patterned by a patterning process. As shown in FIG. 12, a buffer layer 103, a first barrier layer 102 and a first aperture k6 are formed. The first aperture k6 is located in a hole area 300, and the buffer layer 103 and the first barrier layer 102 within the first aperture k6 are etched away to expose the rigid substrate 2. The first aperture k6 includes a first hole diameter area k61 located in the first barrier layer 102 and a second hole diameter area k62 located in the buffer layer 103, and a hole diameter of the second hole diameter area k62 is larger than that of the first hole diameter area k61. That is, an orthographic projection of the first hole diameter area k61 on the rigid substrate 2 falls within a range of an orthographic projection of the second hole diameter area k62 on the rigid substrate 2. In other words, the first barrier layer 102 includes a second end face facing the first aperture k6, and the buffer layer 103 includes a third end face facing the first aperture k6. In a direction parallel to the rigid substrate, the second end face protrudes beyond the third end face towards the first aperture. A barrier eave 107 is formed at a position on the first barrier layer 102 corresponding to the second hole diameter area k62. A length of the barrier eave 107 ranges from about 0.2 microns to 2 microns, and a thickness of the buffer layer 103 ranges from about 0.2 microns to 2 microns. In an exemplary embodiment, an etching rate of the first barrier layer 102 is less than an etching rate of the buffer layer 103 during the patterning process. The first barrier layer 102 may be made of silicon oxide (SiOₓ), and the buffer layer may be made of silicon nitride (SiNₓ), and dry etching is used as the etching method. The buffer layer 103 may also be made of an organic material such as polyimide or other liftable materials, which are formed on the rigid substrate by coating. FIG. 12 is a schematic diagram of a structure after the barrier eave is formed according to another exemplary embodiment of the present disclosure.

Subsequently, a first flexible base substrate thin film is coated on the base substrate on which the above patterns are formed, and cured into a film to form a first flexible base substrate layer 101. As shown in FIG. 13, the first flexible base substrate layer 101 covers the first barrier layer 102 and fills the first aperture k6. In an exemplary embodiment, a material of the first flexible base substrate layer may be polyimide. FIG. 13 is a schematic diagram of a structure after the first barrier layer is formed according to another exemplary embodiment of the present disclosure.

Subsequently, a second barrier thin film is deposited on the base substrate on which the above patterns are formed, and the second barrier thin film is patterned by a patterning process to form a second barrier layer 104, as shown in FIG. 14. A second aperture k7 is formed in the second barrier layer 104, and corresponds to the position of the first aperture. The second barrier layer 104 includes a fourth end face facing the second aperture. In the direction parallel to the rigid substrate, the fourth end face is located between the second end face and the third end face. FIG. 14 is a schematic diagram of a structure after the second barrier layer is formed according to another exemplary embodiment of the present disclosure.

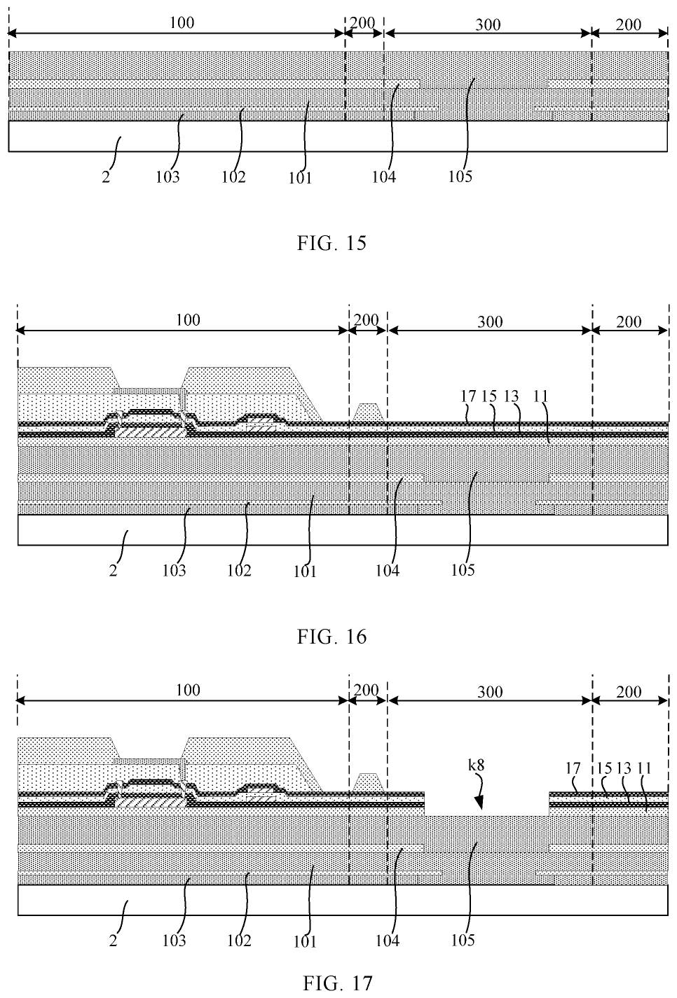

Subsequently, a second flexible base substrate thin film is coated on the base substrate on which the above patterns are formed and cured into a film to form a second flexible base substrate layer 105, as shown in FIG. 15. The second flexible base substrate layer 105 fills the second aperture k7. In an exemplary embodiment, a material of the second flexible base substrate layer may be polyimide. FIG. 15 is a schematic diagram of a structure after the second barrier layer is formed according to another exemplary embodiment of the present disclosure.

(2) Patterns of a drive structure layer and a connection line are prepared on the base substrate. For the relevant preparation process, reference may be made to the preparation process of the previous embodiments, which will not be repeated here.

(3) A planarization layer is formed on the base substrate on which the above patterns are formed. For the relevant preparation process, reference may be made to the preparation process of the previous embodiments, which will not be repeated here.

(4) Forming a pattern of an anode on the base substrate on which the above patterns are formed. For the relevant preparation process, reference may be made to the preparation process of the previous embodiments, which will not be repeated here.

(5) Forming a pixel definition layer and an isolation dam on the base substrate on which the above patterns are formed, namely the structure as shown in FIG. 16. For the relevant preparation process, reference may be made to the preparation process of the previous embodiments, which will not be repeated here. FIG. 16 is a schematic diagram of a structure after the pixel definition layer and the isolation dam are formed according to another exemplary embodiment of the present disclosure.

(6) Patterning a fourth insulation layer 17 on the base substrate on which the above patterns are formed by a patterning process to form a pattern of a third aperture k8, as shown in FIG. 17. The third aperture k8 is formed in the hole area 300 and corresponds to the second aperture. The composite insulation layers (the first insulation layer 11, the second insulation layer 13, the third insulation layer 14, and the fourth insulation layer 17) within the third aperture k8 are etched away to expose the second flexible base substrate layer 105. The composite insulation layer includes a first end face facing the third aperture. In the direction parallel to the rigid substrate 2, the first end face is flush with the fourth end face, and the second end face protrudes beyond the first end face towards the third aperture. After this patterning process, film layer structures of the pixel island area 100 and the connection bridge area 200 remain unchanged. After the third aperture k8 is formed, the photoresist mask for forming the third aperture k8 is not lifted off. FIG. 17 is a schematic diagram of a structure after the third aperture is formed according to another exemplary embodiment of the present disclosure.

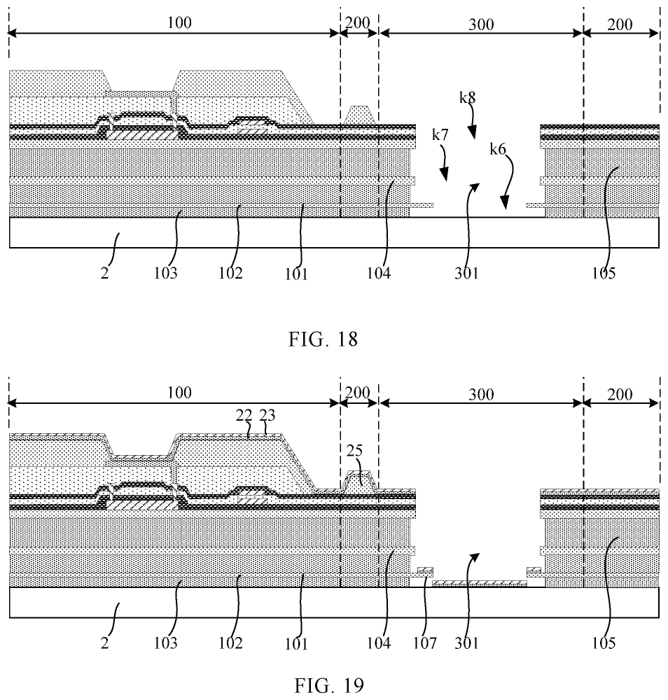

(7) Etching the first flexible base substrate layer 101 and the second flexible base substrate layer 105 on the base substrate on which the above patterns are formed. As shown in FIG. 18, the first aperture k6 and the second aperture k7 of the hole area 300 are exposed to form an aperture 301. After this patterning process, the film layer structures of the pixel island area 100 and the connection bridge area 200 remain unchanged. FIG. 18 is a schematic diagram of a structure after forming the aperture according to another exemplary embodiment of the present disclosure.

(8) Sequentially evaporating an organic light emitting material and a cathode metal thin film on the base substrate on which the above patterns are formed to form patterns of an organic light emitting layer 22 and a cathode 23. As shown in FIG. 19, in the pixel island area 100, the organic light emitting layer 22 is connected to the anode 20 in an pixel opening area, and the cathode 23 is provided on the organic light emitting layer 22. In the connection bridge area 200, the organic light emitting layer 22 and the cathode 23 cover the isolation dam 25. In the hole area 300, the organic light emitting layer 22 and the cathode 23 are separated by a side face of the composite insulation layer towards the aperture 301. The organic light emitting layer 22 and the cathode 23 within the aperture 301 are separated by the barrier eave 107. The organic light emitting layer 22 and the cathode 23 within the aperture 301 may partially block the opening between the barrier eave 107 and the rigid substrate 2. FIG. 19 is a schematic diagram of a structure after the organic light emitting layer and the cathode are formed according to another exemplary embodiment of the present disclosure.

(9) Depositing an inorganic encapsulation thin film on the base substrate on which the above patterns are formed. As shown in FIG. 20, an encapsulation layer 24 covering the pixel island area 100, the connection bridge area 200 and the hole area 300 is formed. In the pixel island area 100, the encapsulation layer 24 covers the cathode 23. In the connection bridge area 200, the encapsulation layer 24 is provided on the cathode 23. In the hole area 300, the encapsulation layer 24 is provided on the cathode 23 and wraps the composite insulation layer and the base substrate 10. Since a deep groove structure with a relatively small notch is formed between the barrier eave 107 and the rigid substrate 2, and the organic light emitting layer 22 and the cathode 23 within the aperture 301 block part of the opening, the amount of inorganic packaging material deposited below the barrier eave 107 is small, the encapsulation layer is small or even discontinuous, and is prone to breakage, thus forming a fracture area of the encapsulation layer 24. FIG. 20 is a schematic diagram of a structure after the encapsulation layer is formed according to another exemplary embodiment of the present disclosure.

(10) Forming a display substrate 1 as shown in FIG. 11 by lifting off the base substrate 10 from the rigid substrate 2 using a laser process.

As can be seen from the preparation process of the display substrate of the present exemplary embodiment, as shown in FIG. 20, since a deep groove structure with a relatively small notch is formed between the barrier eave 107 and the rigid substrate 2, and the organic light emitting layer 22 and the cathode 23 deposited on the rigid substrate 2 within the aperture 301 block part of the opening, the amount of inorganic packaging material deposited below the barrier eave 107 is small, a thickness of the encapsulation layer is small or even discontinuous, and is prone to breakage, thus forming a fracture area A of the encapsulation layer 24. During a process of lifting off the base substrate 10 from the rigid substrate 2, the lift-off will be cut off in the fracture zone A, thus preventing the encapsulation layer 24 from being lifted off, thereby improving the reliability of the encapsulation layer and prolonging the service life of the display substrate.

In another embodiment, the second preparation process is:

(1) A base substrate 10 is prepared on a rigid substrate 2.

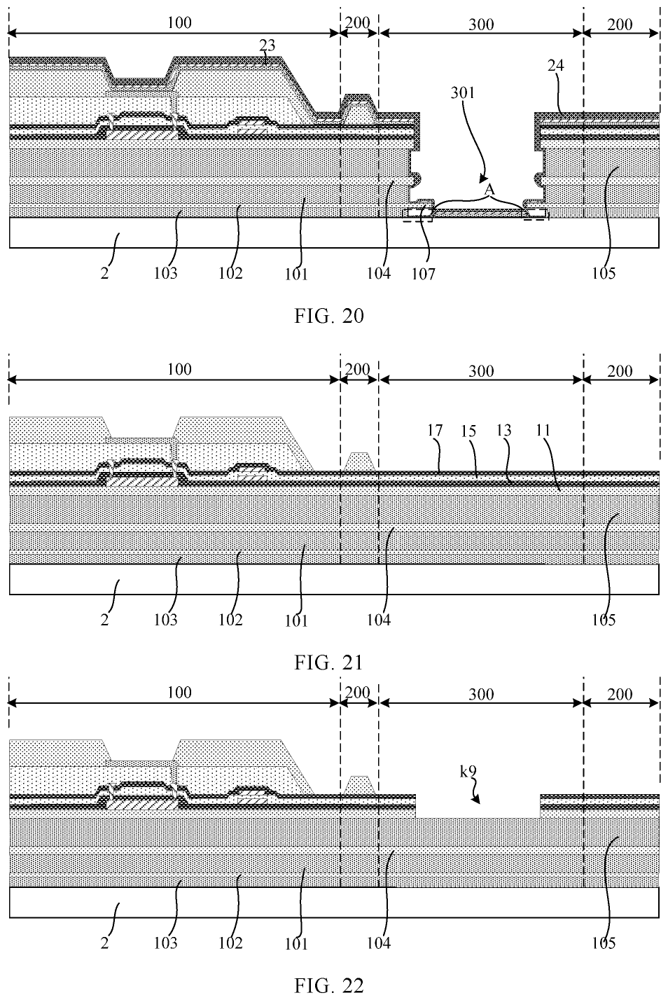

As shown in FIG. 21, a buffer layer thin film is coated on the rigid substrate 2 and cured into a film to form a buffer layer 103. In an exemplary embodiment, a material of the buffer layer 103 may be polyimide. The buffer layer 103 has a thickness ranging from 1 micron to 15 microns. FIG. 21 is a schematic diagram of a structure after a fourth insulation layer is formed according to an exemplary embodiment of the present disclosure.

Subsequently, a first barrier thin film is deposited on the buffer layer 103 to form a first barrier layer 102.

Subsequently, a first flexible base substrate thin film is coated on the first barrier layer 102, and cured into a film to form a first flexible base substrate layer 101.

Subsequently, a second barrier thin film is deposited on the first flexible base substrate layer 101 to form a second barrier layer 104.

Subsequently, a second flexible base substrate thin film is coated on the second barrier layer 104, and cured into a film to form a second flexible base substrate layer 105.

In an exemplary embodiment, thicknesses of the first flexible base substrate layer and the second flexible base substrate layer range from about 2 microns to 10 microns.

(2) Patterns of a drive structure layer and a connection line are prepared on the base substrate. For the relevant preparation process, reference may be made to the preparation process of the previous embodiments, which will not be repeated here.

(3) Planarization layer is formed on the base substrate on which the above patterns are formed. For the relevant preparation process, reference may be made to the preparation process of the previous embodiments, which will not be repeated here.

(4) A pattern of an anode is formed on the base substrate on which the above patterns are formed. For the relevant preparation process, reference may be made to the preparation process of the previous embodiments, which will not be repeated here.

(5) A pixel definition layer and an isolation dam are formed on the base substrate on which the above patterns are formed. For the relevant preparation process, reference may be made to the preparation process of the previous embodiments, which will not be repeated here.

(6) A fourth insulation layer is formed on the base substrate on which the above patterns are formed by a patterning process. As shown in FIG. 22, a pattern of a first window k9 is formed. The first window k9 is formed in the hole area 300, and the composite insulation layer in the first window k9 is etched away to expose the second flexible base substrate layer 105. The composite insulation layer includes a first end face facing the first window k9. After this patterning process, film layer structures of the pixel island area 100 and the connection bridge area 200 remain unchanged. After the first window k9 is formed, the photoresist mask for forming the first window k9 is not lifted off. FIG. 22 is a schematic diagram of a structure after the first window is formed according to another exemplary embodiment of the present disclosure.

(7) The second flexible base substrate layer 105 is etched on the base substrate on which the above patterns are formed. As shown in FIG. 23, a second window k10 is formed. The second window k10 is formed in the hole area 300 and corresponds to the position of the first window k9, wherein an orthographic projection of the second window k10 on the rigid substrate 2 coincides with an orthographic projection of the first window k9 on the rigid substrate 2. The second flexible base substrate layer 105 within the second window k10 is etched away to expose the second barrier layer 104. After this patterning process, the film layer structures of the pixel island area 100 and the connection bridge area 200 remain unchanged. After the second window k10 is formed, the photoresist mask for forming the first window k9 is not lifted off. FIG. 23 is a schematic diagram of a structure after the second window is formed according to another exemplary embodiment of the present disclosure.

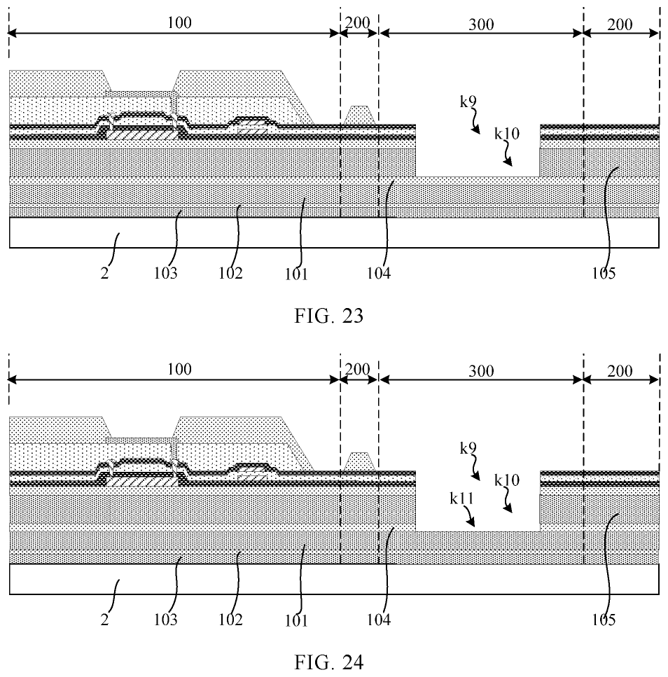

(8) The second barrier layer 104 is etched on the base substrate on which the above patterns are formed. As shown in FIG. 24, a third window k11 is formed. The third window k11 is formed in the hole area 300 and corresponds to the position of the second window k10, wherein an orthographic projection of the third window k11 on the rigid substrate 2 coincides with the orthographic projection of the second window k10 on the rigid substrate 2. The second barrier layer 104 within the third window k11 is etched away to expose the first flexible base substrate layer 101. The second barrier layer 104 includes a fourth end face facing the third window, and the first end face is flush with the fourth end face. After this patterning process, the film layer structures of the pixel island area 100 and the connection bridge area 200 remain unchanged. After the third window k11 is formed, the photoresist mask for forming the first window k9 is not lifted off. FIG. 24 is a schematic diagram of a structure after the third window is formed according to another exemplary embodiment of the present disclosure.

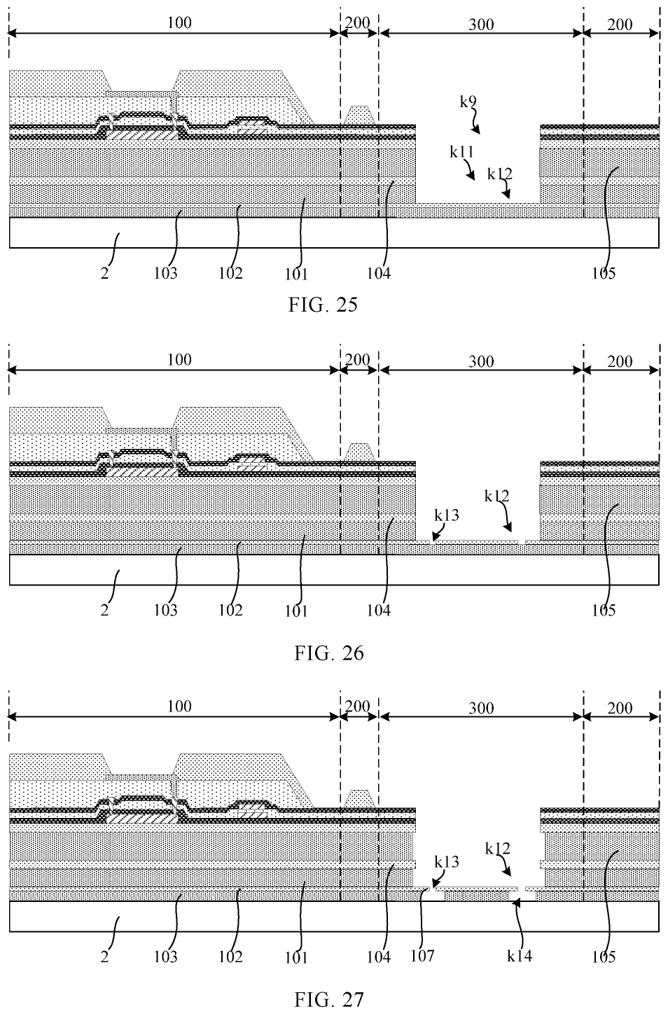

(9) The first flexible base substrate layer 101 is etched on the base substrate on which the above patterns are formed. As shown in FIG. 25, a fourth window k12 is formed. The fourth window k12 is formed in the hole area 300 and corresponds to the position of the third window k11. The first flexible base substrate layer 101 within the fourth window k12 is etched away to expose the first barrier layer 102. After this patterning process, the film layer structures of the pixel island area 100 and the connection bridge area 200 remain unchanged. FIG. 25 is a schematic diagram of a structure after the fourth window is formed according to another exemplary embodiment of the present disclosure.

In an exemplary embodiment, steps (7) to (9) may be completed in a single etching, that is, the second flexible base substrate layer, the second barrier layer and the first flexible base substrate layer are etched in a single etch process.

(10) The first barrier layer 102 is patterned on the base substrate on which the above patterns are formed by the patterning process. As shown in FIG. 26, a pattern of a via hole k13 is formed. The via hole k13 is formed in the first barrier layer 102 of the hole area 300 and the first barrier layer 102 within the via hole k13 is etched away to expose the buffer layer 103. The via hole k13 is an annular hole and is provided along the circumferential direction of the fourth window k12. An orthographic projection of the via hole k13 on the rigid substrate 2 falls within a range of the orthographic projection of the fourth window k12 on the rigid substrate 2. The first barrier layer 102 outside the via hole k13 includes a second end face facing the via hole. In a direction parallel to the rigid substrate 2, the second end face protrudes beyond the first end face along a side facing the via hole k13. A hole diameter of the via hole k13 ranges between about 0.2 microns and 2 microns. After this patterning process, the film layer structures of the pixel island area 100 and the connection bridge area 200 remain unchanged, and the photoresist mask for forming the via hole k13 is not lifted off. FIG. 26 is a schematic diagram of a structure after the via hole is formed according to another exemplary embodiment of the present disclosure.

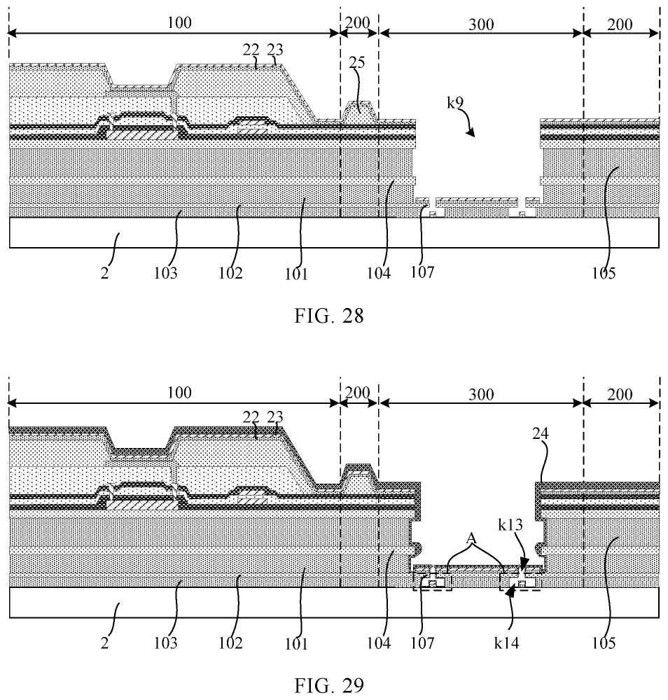

(11) The buffer layer 103 is etched on the base substrate on which the above patterns are formed. As shown in FIG. 27, an inner enlarging hole k14 is formed in the buffer layer 103. The inner enlarging hole k14 is formed in the hole area 300 and corresponds to the position of the via hole k13. The buffer layer 103 within the inner enlarging hole k14 is etched away to expose the rigid substrate 2. A hole diameter of the inner enlarging hole k14 is larger than that of the via hole k13. Here, the hole diameter of the inner enlarging hole k14 may be understood as a width of the inner enlarging hole k14, that is, the width in the horizontal direction of FIG. 27. A barrier eave 107 is formed at the position of the first barrier layer 102 on two sides of the via hole k13 corresponding to the inner enlarging hole k14, that is the buffer layer 102 outside the inner enlarging hole k14 includes a third end face facing the inner enlarging hole k14. In a direction parallel to the rigid substrate 2, the third end face is located between the first end face and the second end face. In another example, the third end face is flush with the first end face. A length of the barrier eave 107 ranges from about 0.2 microns to 2 microns. After this patterning process, the film layer structures of the pixel island area 100 and the connection bridge area 200 remain unchanged. FIG. 27 is a schematic diagram of a structure after the inner enlarging hole is formed according to another exemplary embodiment of the present disclosure.

(12) An organic light emitting material and a cathode metal thin film are sequentially evaporated on the base substrate on which the above patterns are formed to form patterns of an organic light emitting layer 22 and a cathode 23. As shown in FIG. 28, in the pixel island area 100, the organic light emitting layer 22 is connected to the anode 20 in an pixel opening area, and the cathode 23 is provided on the organic light emitting layer 22. In the connection bridge area 200, the organic light emitting layer 22 and the cathode 23 cover the isolation dam 25. In the hole area 300, the organic light emitting layer 22 and the cathode 23 are separated by a side face of the composite insulation layer facing the first window k9, i.e. by the first end face, and are separated at the position of the barrier eave 107, i.e. by the second end face. FIG. 28 is a schematic diagram of a structure after the organic light emitting layer and the cathode are formed according to another exemplary embodiment of the present disclosure.

(13) An inorganic encapsulation thin film is deposited on the base substrate on which the above patterns are formed. As shown in FIG. 29, an encapsulation layer 24 covering the pixel island area 100, the connection bridge area 200 and the hole area 300 is formed. In the pixel island area 100, the encapsulation layer 24 covers the cathode 23. In the connection bridge area 200, the encapsulation layer 24 is provided on the cathode 23. In the hole area 300, the encapsulation layer 24 is provided on the cathode 23 and wraps the composite insulation layer and the base substrate 10. Due to the barrier of the barrier eave 107, as the inorganic encapsulation thin film is continuously deposited, the hole diameter of the via hole k13 is gradually reduced, and a small amount of the inorganic encapsulation thin film is deposited in the inner enlarging hole k14, that is, a thickness of the encapsulation layer in the inner enlarging hole k14 is small or even discontinuous, and is prone to breakage, thus forming a fracture area of the encapsulation layer 24. In an exemplary embodiment, the hole diameter of the via hole k13 is approximately equal to the thickness of the encapsulation layer 24 and deposition of the inorganic encapsulation thin film within the inner enlarging hole k14 may be further restricted. FIG. 29 is a schematic diagram of a structure after the encapsulation layer is formed according to another exemplary embodiment of the present disclosure.

(14) A display substrate 1 as shown in FIG. 11 is formed by lifting off the base substrate 10 from the rigid substrate 2 using a laser process.

As can be seen from that preparation process of the display substrate of the present exemplary embodiment, due to the barrier of the barrier eave 107 and the continuous deposition of the inorganic encapsulation thin film, the hole diameter of the via hole k13 is gradually reduced, and a small amount of the inorganic encapsulation thin film is deposited in the inner enlarging hole k14, that is, the thickness of the encapsulation layer within the inner enlarging hole k14 is small or even discontinuous, and prone to breakage, thus forming a fracture area A by the encapsulation layer 24 formed under the barrier eave 107, and during a process of lifting off of the base substrate 10 from the rigid substrate 2, the lift-off will be cut off in the fracture zone, thus preventing the encapsulation layer 24 from being lifted off, thereby improving the reliability of the encapsulation layer and prolonging the service life of the display substrate.

An embodiment of the present disclosure further provides a method for preparing a display substrate, including:

forming multiple pixel island areas separated from each other, multiple hole areas and a connection bridge area connecting the multiple pixel island areas on a base substrate, wherein the base substrate of a hole area is provided with an aperture, and a side of the base substrate close to the aperture is provided with a barrier structure;

forming an encapsulation layer, wherein the encapsulation layer covers a sidewall of the base substrate close to the aperture, and the barrier structure is configured to form a fracture zone on the encapsulation layer that can break when the base substrate is lifted off from the rigid substrate.

In an exemplary embodiment, forming the multiple pixel island areas separated from each other, the multiple hole areas and the connection bridge area connecting the multiple pixel island areas on the base substrate includes:

forming a first flexible base substrate layer;

sequentially depositing a first barrier thin film, a buffer thin film and a second barrier thin film on the first flexible base substrate layer, and patterning the second barrier thin film by a patterning process to form a first barrier layer, a buffer layer, a second barrier layer and a first opening which are stacked, wherein the first opening is provided in a hole area and exposes the first flexible base substrate layer;

etching the buffer layer, with respect to surfaces of the first barrier layer and the second barrier layer facing the first opening, a surface of the buffer layer facing the first opening is recessed in a direction away from the first opening to form a barrier groove with a notch facing the first opening, a depth of the barrier groove ranges from 0.2 microns to 2 microns, and a width of the barrier groove ranges from 0.2 microns to 2 microns.

In an exemplary embodiment, forming the multiple pixel island areas separated from each other, the multiple hole areas and the connection bridge area connecting the multiple pixel island areas on the base substrate includes:

forming a buffer layer on a rigid substrate;

depositing a first barrier thin film on the buffer layer, patterning the first barrier thin film by a patterning process to forming a first barrier layer and a first aperture, wherein the first aperture is located in the hole area, the buffer layer and the first barrier layer within the first aperture are etched away to expose the rigid substrate, the first aperture includes a first hole diameter area formed in the first barrier layer and a second hole diameter area formed in the buffer layer, a hole diameter of the first hole diameter area is smaller than a hole diameter of the second hole diameter area, a barrier eave is formed at the corresponding position of the first barrier layer and the second hole diameter area, and the barrier eave forms a barrier structure.

In an exemplary embodiment, forming the multiple pixel island areas separated from each other, the multiple hole areas and the connection bridge area connecting the multiple pixel island areas on the base substrate includes:

forming a buffer layer on a rigid substrate;

depositing a first barrier thin film on the buffer layer, and patterning the first barrier thin film by a patterning process to form a first barrier layer and a via hole, wherein the via hole is located in the hole area, the via hole is an annular hole, the first barrier layer within the via hole is etched away to expose the buffer layer, and the hole diameter of the via hole ranges between 0.2 microns and 2 microns; and

etching the buffer layer to form an inner enlarging hole, wherein the inner enlarging hole is formed in the hole area and corresponds to the position of the via hole, the buffer layer within the inner enlarging hole is etched away to expose the rigid substrate, the hole diameter of the inner enlarging hole is larger than that of the via hole, a barrier eave is formed at the position of the first barrier layer on two sides of the via hole corresponding to the inner enlarging hole, and the barrier eave forms a barrier structure.

An embodiment of the present disclosure further provides a display apparatus including the display substrate of the aforementioned embodiments.

The display apparatus may be any product or component with a display function, such as a mobile phone, a tablet computer, a television, a display, a laptop computer, a digital photo frame, or a navigator.

Although the embodiments disclosed in the present disclosure are as above, the described contents are only embodiments used for convenience of understanding the present disclosure and are not intended to limit the present disclosure. Any person skilled in the art to which the present disclosure pertains may make any modification and variation in implementation forms and details without departing from the spirit and scope disclosed in the present disclosure. However, the scope of patent protection of the present disclosure is still subject to the scope defined by the appended claims.

1. A display substrate, comprising a plurality of pixel island areas separated from one another, a plurality of hole areas and a connection bridge area connecting the plurality of pixel island areas, wherein a hole area comprises a base substrate and an encapsulation layer, the base substrate is provided with an aperture and provided with a barrier structure on a side of the base substrate close to the aperture, and the encapsulation layer covers the side of the base substrate close to the aperture.

2. The display substrate according to claim 1, wherein the barrier structure is provided as a barrier groove, a notch of the barrier groove faces the aperture, and a thickness of the encapsulation layer inside the barrier groove is smaller than a thickness of the encapsulation layer outside the barrier groove, or the encapsulation layer inside the barrier groove is discontinuous.

3. The display substrate according to claim 2, wherein the hole area further comprises a composite insulation layer provided on the base substrate, the encapsulation layer covers the composite insulation layer, the composite insulation layer comprises a first end face facing the aperture, the base substrate comprises a first barrier layer, a buffer layer and a second barrier layer which are stacked, and the first barrier layer comprises a second end face facing the aperture, the buffer layer comprises a third end face facing the aperture, and the second barrier layer comprises a fourth end face facing the aperture;
in a direction parallel to the base substrate, a distance between the second end face and the first end face is smaller than a distance between the third end face and the first end face, a distance between the fourth end face and the first end face is smaller than the distance between the third end face and the first end face, the third end face is provided as a groove bottom of the barrier groove, and opposite surfaces of the first barrier layer and the second barrier layer are provided as sidewalls of the barrier groove.

4. The display substrate according to claim 3, wherein the base substrate comprises a first flexible base substrate layer and a second flexible base substrate layer, the first flexible base substrate layer is provided on a side of the first barrier layer away from the buffer layer, the second flexible base substrate layer is provided on a side of the second barrier layer away from the buffer layer, the first flexible base substrate layer comprises a fifth end face facing the aperture, and the second flexible base substrate layer comprises a sixth end face facing the aperture;
in the direction parallel to the base substrate, a distance between the fifth end face and the first end face is larger than the distance between the second end face and the first end face, larger than the distance between the fourth end face and the first end face, and smaller than the distance between the third end face and the first end face, a distance between the sixth end face and the first end face is larger than the distance between the second end face and the first end face, larger than the distance between the fourth end face and the first end face, and smaller than the distance between the third end face and the first end face.

5. The display substrate according to claim 4, wherein the fifth end face is flush with the sixth end face, and the second end face is flush with the third end face.

6. The display substrate according to claim 2, wherein the barrier groove has a depth ranging from 0.2 microns to 2 microns and a width ranging from 0.2 microns to 2 microns.

7. The display substrate according to claim 2, wherein in a direction perpendicular to the base substrate, a width of the barrier groove is smaller than or equal to the thickness of the encapsulation layer outside the barrier groove.

8. The display substrate according to claim 1, wherein the barrier structure is provided as a barrier eave, the barrier eave extends into the aperture, the barrier eave is configured to form a groove structure with the rigid substrate, a thickness of the encapsulation layer within the groove structure is smaller than a thickness of the encapsulation layer outside the groove structure, or the encapsulation layer within the groove structure is discontinuous.

9. The display substrate according to claim 8, wherein the base substrate comprises a buffer layer and a first barrier layer provided on the buffer layer, the first barrier layer extends into the aperture and protrudes beyond the buffer layer to form an eave structure, and the barrier eave comprises a portion of the first barrier layer protruding beyond the buffer layer.

10. The display substrate according to claim 9, wherein a length of the first barrier layer protruding beyond the buffer layer ranges from 0.2 microns to 2 microns, and a thickness of the buffer layer ranges from 0.2 microns to 2 microns.

11. The display substrate according to claim 8, further comprising an organic light emitting layer and a cathode, the organic light emitting layer and the cathode of the hole area are partially provided on the barrier eave.

12. A display apparatus comprising the display substrate according to claim 1.

13. A method for preparing a display substrate, comprising:
forming a plurality of pixel island areas separated from each other, a plurality of hole areas and a connection bridge area connecting the plurality of pixel island areas on the base substrate, the base substrate of a hole area is provided with an aperture, and a barrier structure is provided on a side of the base substrate close to the aperture; and
forming an encapsulation layer, wherein the encapsulation layer covers the side of the base substrate close to the aperture.

14. The display substrate according to claim 3, wherein the barrier groove has a depth ranging from 0.2 microns to 2 microns and a width ranging from 0.2 microns to 2 microns.

15. The display substrate according to claim 4, wherein the barrier groove has a depth ranging from 0.2 microns to 2 microns and a width ranging from 0.2 microns to 2 microns.

16. The display substrate according to claim 5, wherein the barrier groove has a depth ranging from 0.2 microns to 2 microns and a width ranging from 0.2 microns to 2 microns.

17. The display substrate according to claim 3, wherein in a direction perpendicular to the base substrate, a width of the barrier groove is smaller than or equal to the thickness of the encapsulation layer outside the barrier groove.

18. The display substrate according to claim 4, wherein in a direction perpendicular to the base substrate, a width of the barrier groove is smaller than or equal to the thickness of the encapsulation layer outside the barrier groove.

19. The display substrate according to claim 5, wherein in a direction perpendicular to the base substrate, a width of the barrier groove is smaller than or equal to the thickness of the encapsulation layer outside the barrier groove.
